(19) United States
(12) Patent Application Publication
(10) Pub. No.: US 2023/0177869 A1
(43) Pub. Date: Jun. 8, 2023

(54) BIOMETRIC IMAGING DEVICE COMPRISING COLLIMATING STRUCTURES AND METHOD OF IMAGING IN THE BIOMETRIC IMAGING DEVICE

(71) Applicant: FINGERPRINT CARDS ANACATUM IP AB, GÖTEBORG (SE)

(72) Inventors: Matthew Liptrot, VIRUM (DK); Arvid Hammar, GÖTEBORG (SE); Hans Martinsson, GÖTEBORG (SE)

(21) Appl. No.: 17/920,073

(22) PCT Filed: Apr. 27, 2021
(86) PCT No.: PCT/SE2021/050384

§ 371 Date: Oct. 20, 2022

(30) Foreign Application Priority Data
May 7, 2020 (SE) 2050531-9

(51) Int. Cl. G06V 40/13; G06V 40/12; G02B 27/30; H01L 27/146

(52) U.S. Cl. CPC G06V 40/1324; G06V 40/1394; G02B 27/30; H01L 27/14625; G02B 5/201

(57) ABSTRACT

An optical biometric imaging device comprising: an image sensor comprising a plurality of photodetector pixels; a plurality of collimating structures arranged above the image sensor, the collimating structures being configured to limit the incident angle of light reaching the image sensor to be lower than a first predetermined incident angle Θ₁; wherein at least a subset of the collimating structures comprises a light-blocking element configured to block light having an incident angle lower than a second predetermined incident angle Θ₂, the second incident angle being lower than the first incident angle, wherein the light-blocking element is configured to allow light having an incident angle between the first and second predetermined incident angles to pass and wherein the light-blocking element is configured to block light within a first predetermined wavelength range.

### FIELD OF THE INVENTION

The present invention relates to an optical biometric imaging device suitable for integration in a display panel. In particular, the invention relates to an optical biometric imaging device suitable for fingerprint sensing.

### BACKGROUND OF THE INVENTION

Biometric imaging systems are widely used as means for increasing the convenience and security of personal electronic devices, such as mobile phones etc. Fingerprint sensing systems in particular are now included in a large proportion of all newly released consumer electronic devices, such as mobile phones.

Optical fingerprint sensors have been known for some time and may be a feasible alternative to e.g. capacitive fingerprint sensors in certain applications such as for use as under-display sensors. Optical fingerprint sensors may for example be based on the pinhole imaging principle and/or may employ micro-structures, e.g. collimators or microlenses to collect and steer incoming light towards an image sensor.

Optical fingerprint sensors may give rise to fingerprint images exhibiting two different types of contrast. One type of contrast is due to the variations in refractive indices between the cover structure of the sensor, such as a display glass, and the different areas of finger. For the parts of the finger that are not in contact with the cover structure, e.g. the fingerprint valley, light reaching the surface of the cover structure at an angle greater than the critical angle is reflected due to the difference in refractive index between glass and air, and a contrast is thus seen in comparison to the parts of the skin that are in contact with the glass for which the critical angle is significantly larger. The other type of contrast is that of a typical camera system, where light reflection off the different skin surfaces (ridges and valleys) generates a similar contrast as would be present in a photograph where the ridges appear lighter and the valleys appear darker, which is opposite to the previously described contrast.

A mixture of the different types of contrasts within a single image generates problems when the dominance of one mechanism over the other is not stable across the acquired image. This is a common occurrence when imaging dry fingers, whereas naturally moist fingers offer very strong index-matched contrast throughout, offering good delineation between contiguous ridge borders and the valley (non-contact) regions. The difference between images with a single contrast versus those with a mixture of contrasts is so substantial that it is the cause of problematic performance in so-called “cross-match” scenarios (biometrical matching of dry fingers versus moist/normal fingers). In addition, the strong index-matched contrast mechanism of normal fingers can be well-matched to the camera-type contrast that is created when a 2D spoof is presented on top of the sensor cover structure.

Accordingly, it is desirable to address the above issues relating to different types of image contrast in optical biometric imaging devices.

### SUMMARY

In view of above-mentioned and other drawbacks of the prior art, it is an object of the present invention to provide an improved biometric imaging device suitable for use under a display cover glass in an electronic user device and where the issues relating to the different types of image contrast can be addressed.

According to a first aspect of the invention, there is provided a biometric imaging device comprising: an image sensor comprising a plurality of photodetector pixels; a plurality of collimating structures arranged above the image sensor, the collimating structures being configured to limit the incident angle of light reaching the image sensor to be lower than a first predetermined incident angle (Θ₁); wherein at least a subset of the collimating structures comprises a light-blocking element configured to block light having an incident angle lower than a second predetermined incident angle (Θ₂), the second incident angle being lower than the first incident angle, and wherein the light-blocking element is configured to allow light having an incident angle between the first and second predetermined incident angles to pass.

The collimating structures, i.e. collimators, are configured to receive light having been reflected off a fingertip. The incident angle of light reaching the collimators may vary greatly depending on the properties of the material between the collimator and the finger, and the function of the collimating structure is to collect and steer the light towards the image sensor so that light reaching the image sensor has an incident angle which is lower than the first predetermined incident angle. Thereby, the light reaching the image sensor has the shape of a cone whose solid angle is defined by the collimator properties. The collimating structures may be embodied in many different ways as will be described in the following. The collimating structures may for example comprise several aperture layers, microlenses, and/or elongated openings in order to achieve the desired collimating functionality.

Moreover, for the subset of the collimating structures comprising the light-blocking element, light having an incident angle smaller than a second predetermined angle is blocked. In practice, this means that orthogonal light, or light within a narrow angle range centered around orthogonal light, is blocked by the light-blocking element and prevented from reaching the image sensor.

The present invention is based on the realization that it is possible to distinguish between two types of contrasts of biometric images using the described optical biometric imaging device comprising a combination of collimating structures with and without light-blocking elements. Thereby, the subsequent image processing can be simplified to make it possible to verify fingerprints where the contrast type may vary over the fingerprint or in situations where the contrast, due to a disparate environment or skin condition, is very different from that of previously approved examples (i.e. a cross-match scenario). The separation of the two different types of contrasts also provides a unique opportunity to apply anti-spoof detection, as the concurrent replication of both imaging contrasts in a single physical spoof (2D or 3D) will be extremely challenging.

Moreover, the light-blocking element is configured to block light within a first predetermined wavelength range. The light-blocking element may for example be configured to block a subrange of the visible range. The first predetermined wavelength range is thereby a subrange of the wavelength range for visible light. Thereby, it can be controlled if the light-blocking element should block light reflected by the finger by controlling the wavelength of light illuminating the finger. In various embodiments, the light-blocking element may be configured to act as a low-pass filter, a high-pass filter, a band-pass filter or a band-stop filter, for example within the visible wavelength range. In some embodiments, the light-blocking element may be referred to as a color filter where only a selected color is transmitted. In some implementations, the first wavelength range may also extend into the IR (infrared) or UV (ultraviolet) wavelength range.

According to one embodiment of the invention, the light-blocking elements are preferably configured such that biometric images formed based on pixels receiving light from collimating structures having a light-blocking element has a first contrast type and biometric images formed based on pixels receiving light from collimating structures without a light-blocking element have a second contrast type different from the first contrast type. The first contrast type, based on light reaching the pixel from the wider angles, will thereby be a camera type contrast where the ridges of the fingerprint will appear as brighter and the valleys will appear as darker regions in the resulting image. The second contrast type will often be dominated by a reverse image contrast, which may be referred to as an index-matched contrast where the ridges will appear as darker regions and the valleys will be brighter regions in the resulting image. However, the pixels receiving light from collimating structures without a light-blocking element will receive both orthogonal light and angled light, and the resulting image will therefore show a mix of the two types of contrast. The optical properties of the interface between the finger and the outer surface of the imaging device, together with the properties of the finger as such, will determine if the contrast of the resulting image is predominantly of the camera type or of the index-matched type, or an even mix therebetween. As mentioned above, the dominating contrast type may also vary over the area of the fingerprint.

According to one embodiment of the invention, every second collimating structure in the array of collimating structures may comprise a light-blocking element. For a rectangular array of collimating structures, this will result in a chessboard/checkerboard pattern. However, the array of collimating structures may also have other configurations such as hexagonal. Moreover, it is not required that the pixels of the image sensor have the same array configuration as the collimating structure, and it also is not required that there is a 1:1 relation between the number and size of pixels and the number and size of collimating structures.

According to one embodiment of the invention, a first subset of collimating structures comprises light-blocking elements configured to block light within a first predetermined wavelength range, and a second subset of collimating structures comprises light-blocking elements configured to block light within a second predetermined wavelength range different from the first wavelength range. The first and second wavelength ranges are preferably non-overlapping wavelength ranges within or near the wavelength range for visible light, i.e. approximately 400-750 nm. By using light-blocking elements acting as filters for light of different wavelengths, the contrast type to capture for each collimator structure can be controlled by controlling the light illuminating the finger.

According to one embodiment of the invention, each collimating structure may comprise a light-blocking element. Assuming that the wavelength of light illuminating the finger can be controlled, it is possible to capture images of both the described contrast types also for an imaging device where all of the collimating structures comprises a light-blocking element, as long as at least a subset of the light-blocking elements allow a certain subrange of light to pass such that orthogonally oriented light may reach the image sensor. The light-blocking elements in such an embodiment may thereby act as color filters only blocking a certain color of light in the visible range.

According to one embodiment of the invention, the collimating structure comprises: a first aperture layer arranged above the image sensor; a first transparent layer arranged above the first aperture layer; and an array of microlenses arranged above the first transparent layer. The first aperture layer may be arranged directly on the image sensor, or there may be additional layers therebetween. In the same way, the first transparent layer may be arranged directly on the first aperture layer, or there may be additional layers therebetween. The collimating function is thereby achieved by a microlens and an aperture layer, thereby limiting the incident angle of light reaching the image sensor.

According to one embodiment of the invention the biometric imaging device further comprises: a second aperture layer arranged on the first transparent layer; and a second transparent layer arranged on the second aperture layer, wherein the array of microlenses is arranged on the second transparent layer. The second aperture layer is preferably configured such that optical crosstalk between neighboring collimating structures is avoided. The second aperture layer and the second transparent layer may be seen as a part of the collimating structures, but they may also be seen as separate layers which are formed on the image sensor prior to the collimating structure.

For the above described embodiment where the collimating structures comprise one or more aperture layers, the light-blocking elements may be located in the apertures of the first or second aperture layer. For example, the light-blocking element may be a circular element located centrally in a circular aperture of the first aperture layer so that an annulus-shaped opening is formed. However, other options are also possible. The apertures and light-blocking elements may have other shapes, and the light-blocking element may be located in apertures of the second aperture layer or somewhere between the first and second aperture layers. It would also be possible to use more than two aperture layers.

According to one embodiment of the invention, at least a subset of the collimating structures of the biometric imaging device comprise an angle-limiting element configured to limit the angle of incident light reaching the image sensor to be lower than a third predetermined incident angle (Θ₃), the third incident angle being lower than the first incident angle.

The collimating structures having an angle-limiting element can be configured to capture light of the second contrast type, i.e. light which is substantially orthogonal resulting in an image of the index-matched contrast type. Thereby, it is possible to form a biometric imaging device where a first subset of collimating structures have a light-blocking element such that an image having a camera type contrast can be formed, and where the second subset of collimating structures have an angle-limiting element such that an image having an index-matched type contrast can be formed.

The angle-limiting elements may be configured in many different ways. Angle-limiting elements may for example be embodied by the apertures of the above described example of a collimating structure, where apertures of the first and/or second aperture layer can be configured to limit the incident angle to be lower than the third predetermined incident angle. The angle-limiting elements may for example be formed as an aperture which is smaller than apertures in collimating structures comprising a light-blocking element. In a non-limiting example, the angle-limiting element may be an aperture where the size of the opening is the same as the size of a light-blocking element in another collimating structure. It would also be possible to form the angle-limiting elements from separate structures, in or between the apertures of the collimating structure.

It would also be possible to form a collimating structure comprising an angle-limiting element in the form of an aperture which is arranged with an offset in the horizontal plane in relation to another aperture, thereby limiting the incident angle of light reaching the image sensor.

In one embodiment, the first subset of collimating structures is non-overlapping with the second subset of collimating structures, meaning that no collimating structure comprises both a light-blocking element and an angle-limiting element. For example, a subset defining half of the plurality of collimating structures may comprise a light-blocking element and the other half may comprise an angle-limiting element, making it possible to form two images based on the two different types of contrast using only one image capture. For a suitable configuration of the collimating structures, each image could then have a resolution which is half of the full resolution of the imaging device.

According to one embodiment of the invention, the angle-limiting element may be configured to block light within a first predetermined wavelength range, thereby making it possible to control which contrast type to capture by the imaging device by controlling the wavelength of light emitted towards the finger.

There is also provided a display arrangement comprising: a display panel having an array of light emitting elements; and a biometric imaging device according to any one of the preceding claims arranged underneath the display panel. The biometric imaging device may thereby be integrated in or located underneath a display panel so that biometric imaging is made possible over the entire surface of the display. The pixels of the display will then act as light sources for the biometric imaging device so that light emitted from the display panel is reflected by a biometric object in contact with an outer surface of the display panel and reflected back towards the image sensor, where an image of the biometric object can be formed. The biometric object may for example be a fingerprint or a palmprint.

Moreover, the display panel can be controlled to emit light in selected wavelength ranges corresponding to wavelength ranges of the light-blocking filters, such that the light-blocking elements can selectively block orthogonal light based on the color of emitted light.

According to a second aspect of the invention, there is provided a method of imaging in a biometric imaging device comprising: an image sensor comprising a plurality of photodetector pixels and a plurality of collimating structures arranged above the image sensor, the collimating structures being configured to limit the incident angle of light reaching the image sensor to a first predetermined incident angle, wherein at least a subset of the collimating structures comprises a light-blocking element configured to block light having an incident angle lower than a second predetermined incident angle, the second incident angle being lower than the first incident angle, and wherein the light-blocking element is configured to allow light having an incident angle between the first and second incident angles to pass.

The method comprises: forming a first image using pixels located under the subset of collimating structures comprising a light-blocking element; forming a second image using pixels located under the subset of collimating structures not comprising a light-blocking element; and forming a combined image based on the first and second images.

In the described method, the first image will comprise non-orthogonal light reaching the image sensor via collimating structures with a light-blocking element. The first image will thus exhibit a camera-type contrast.

The second image comprises both orthogonal and non-orthogonal light reaching the image sensor via collimating structures without a light-blocking element. The second image will thus exhibit both the camera-type contrast and the index-matched contrast. In an embodiment where half of the collimating structures comprises light-blocking elements, the resolution of the first and second images will be half of the maximum possible resolution.

According to a third aspect of the invention, there is provided a method of imaging in a biometric imaging device arranged under a display panel comprising a plurality of light emitting elements. The biometric imaging device comprises: an image sensor having a plurality of photodetector pixels and a plurality of collimating structures arranged above the image sensor, the collimating structure being configured to limit the incident angle of light reaching the image sensor to a first predetermined incident angle, wherein at least a subset of the collimating structures comprises a light-blocking element configured to block light having an incident angle lower than a second predetermined incident angle, the second incident angle being lower than the first incident angle, the light-blocking element being configured to allow light having an incident angle between the first and second incident angles to pass, and wherein the light-blocking element is configured to block light within a first predetermined wavelength range.

The method comprises: controlling the display panel to emit light only within the first wavelength range; forming a first image based on pixels receiving light from the subset of collimating structures comprising a light-blocking element; controlling the display panel to emit light outside of the first wavelength range; forming a second image based on pixels receiving light from the subset of collimating structures not comprising a light-blocking element; and forming a combined image based on the first and second images.

In the described method, the first image will comprise non-orthogonal light reaching the image sensor via collimating structures with a light-blocking element. The first image will thus exhibit a camera-type contrast.

The second image comprises both orthogonal and non-orthogonal light reaching the image sensor via all collimating structures. The second image will thus exhibit both the camera-type contrast and the index-matched contrast. In an embodiment where half of the collimating structures comprises light-blocking elements, the resolution of the first image will be half of the maximum possible resolution and the and resolution of the second image will be the full resolution since the light-blocking elements are transparent to light outside of the first predetermined wavelength range.

According to a fourth aspect of the invention, there is provided a method of imaging in a biometric imaging device arranged under a display panel comprising a plurality of light emitting elements, the biometric imaging device comprising: an image sensor comprising a plurality of pixels forming a photodetector pixel array and an array of collimating structures arranged above the image sensor, the collimating structure being configured to limit the incident angle of light reaching the image sensor, wherein a first subset of the collimating structures comprises a light-blocking element configured to block light having an incident angle lower than a second predetermined incident angle, the second incident angle being lower than the first incident angle, the light-blocking element of the first subset of collimating structures being configured to allow light having an incident angle between the first and second incident angles to pass, and wherein the light-blocking element of the first subset of collimating structures is configured to block light within a first predetermined wavelength range, and a second subset of the collimating structures comprises a light-blocking element configured to block light having an having an incident angle lower than the second predetermined incident angle, the light-blocking element of the second subset of collimating structures being configured to allow light having an incident angle between the first and second incident angles to pass, and wherein the light-blocking elements of the second subset of collimating structures are configured to block light within a second predetermined wavelength range different from the first wavelength range.

The method comprises controlling the display panel to emit light only within the first wavelength range; forming a first image based on pixels located under the first subset of collimating structures; forming a second image based on pixels located under all collimating structures; controlling the display panel to emit light only within the second wavelength range; forming a third image based on pixels located under the second subset of collimating structures; forming a first combined image based on first and third images; and forming a second combined image based on first combined image and the second image.

Further features of, and advantages with, the present invention will become apparent when studying the appended claims and the following description. The skilled person will realize that different features of the present invention may be combined to create embodiments other than those described in the following, without departing from the scope of the present invention.

### BRIEF DESCRIPTION OF THE DRAWINGS

These and other aspects of the present invention will now be described in more detail, with reference to the appended drawings showing an example embodiment of the invention, wherein:

FIG. 1 schematically illustrates a biometric imaging device according to an embodiment of the invention;

FIGS. 2A-B schematically illustrates details of a biometric imaging device according to an embodiment of the invention;

FIGS. 3A-E schematically illustrates details of a biometric imaging device according to embodiments of the invention;

FIG. 4A-C schematically illustrate features of a biometric image acquired using a device and method according to embodiments of the invention;

FIG. 5 is a flow chart outlining general details of a method according to an embodiment of the invention;

FIG. 6 schematically illustrate selected steps of a method according to an embodiment of the invention;

FIG. 7 is a flow chart outlining general details of a method according to an embodiment of the invention; and

FIG. 8 is a flow chart outlining general details of a method according to an embodiment of the invention.

### DETAILED DESCRIPTION OF EXAMPLE EMBODIMENTS

In the present detailed description, various embodiments of the biometric imaging system according to the present invention are mainly described with reference to a fingerprint imaging sensor suitable for use under a display panel of a consumer device such as a smartphone, tablet computer and the like.

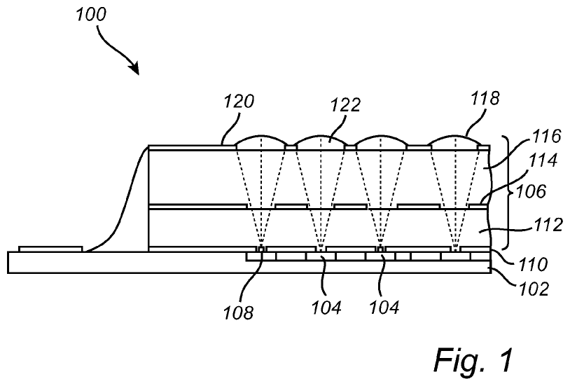

FIG. 1 schematically illustrates a portion of an optical biometric imaging device 100 according to an embodiment of the invention. In particular, FIG. 1 illustrates a cross section of a portion of the biometric imaging device 100, and it should be understood that the imaging device 100 extends further to form an imaging device of suitable size.

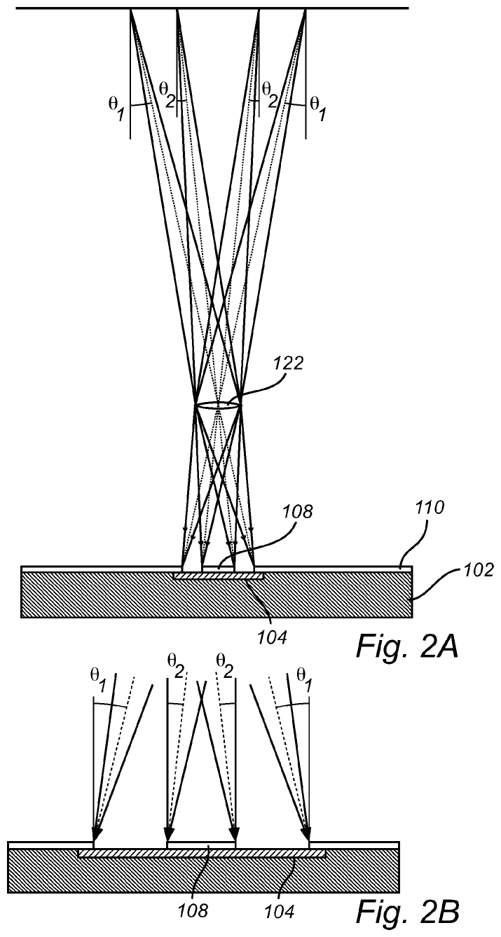

The optical biometric imaging device 100 comprises an image sensor 102 comprising a plurality of photodetector pixels 104. A plurality of collimating structures 106 are arranged above the image sensor 102, the collimating structures 106 being configured to limit the incident angle of light reaching the image sensor to be lower than a first predetermined incident angle Θ₁, with further reference to FIGS. 2A-B illustrating a portion of a collimating structure 106 comprising a light-blocking element 108, the light-blocking element being configured to block light within a first predetermined wavelength range.

Moreover, at least a subset of the collimating structures 106 comprises a light-blocking element 108 configured to block light having an incident angle lower than a second predetermined incident angle, Θ₂, where the second incident angle Θ₂ is lower than the first incident angle Θ₁, i.e. Θ₂<Θ₁. The light-blocking element 108 is further configured to allow light having an incident angle in the range between the first and second predetermined incident angles Θ₁, Θ₂ to pass. The incident angles Θ₁ and Θ₂ are further illustrated in FIGS. 2A-B where it can be seen that light having an incident angle lower than Θ₁ and higher than Θ₂ is allowed to pass through the collimating structure to reach the image sensor 102. In the present context, incident angles are illustrated in relation to the object, FIG. 2A, and in relation to the plane of the first aperture 110 layer, FIG. 2B, which can be assumed to be the same as the plane of the image sensor 102. This means that light which has reached the collimating structure with an incident angle between Θ₁ and Θ₂ is allowed to pass through the collimating structure to reach the image sensor 102.

In a non-limiting example, the first incident angle Θ₁ may be approximately 20° and the second incident angle Θ₂ may be approximately 10°, thereby meaning that light having an incident angle in the range of 10° to 20° reaches the image sensor. The light blocking element 108 is thus here configured to block light having an incident angle between 10° and 0°.

In the example embodiment illustrated in FIG. 1, the collimating structure 106 comprises: a first aperture layer 110 arranged on the image sensor 102; a first transparent layer 112 arranged on the first aperture layer 110; a second aperture layer 114 arranged on the first transparent layer 112; a second transparent layer 116 arranged on the second aperture layer 114, and an array of microlenses 118 arranged on the second transparent layer 116. In some embodiments, the collimating structure 106 may be implemented as only the array of microlenses 118, the first transparent layer 112 and the first aperture layer 110. Moreover, the light-blocking elements 108 may be made from the same material and formed in the same process step as the first aperture layer 110.

The microlenses 118 are aligned with corresponding apertures of the first and second aperture layers 110, 114 so that light reaching the image sensor 102 pass through one microlens 118 and further through corresponding apertures of the first and second aperture layers 110, 114. Here, the apertures of the second aperture layer 114 are preferably configured to prevent optical crosstalk, i.e. such that the light from a neighboring collimating structure only reaches its corresponding vertically aligned pixel 104. The size of the pixel is in the illustrated example configured so that light which has passed through a collimating structure reaches one corresponding pixel.

The material of the first transparent layer 112 may be configured to block light within the infrared wavelength range and is in such embodiments referred to as an IR-cut layer. The first transparent layer 112 may for example be configured to block light having a wavelength higher than approximately 600 nm, thereby ensuring that infrared light or light in the visible range near infrared does not reach the image sensor 102. An IR-cut layer may also be provided as a separate layer in the material stack.

The biometric imaging device 100 may also comprise additional intermediate layers not described herein, such as adhesive layers, as long as the layers are sufficiently transparent to allow light to travel from the microlens to the image sensor without excessive losses.

As further illustrated in FIG. 1, the biometric imaging device comprises an opaque mask layer 120 which comprises openings 122 at the locations of the respective microlenses 118. The opaque mask layer 120 may be arranged on the second transparent layer 116 before or after the microlenses 118 has been arranged on the second transparent layer 116. In either case, the openings 122 of the opaque mask layer 120 have a size which is equal to or smaller than the size of the microlens 118. The opaque mask layer 120 also allows for a sparse arrangement of microlenses 118 in the microlens array such that there is a distance between adjacent microlenses 118.

Moreover, the first aperture layer 110 may be formed from the topmost metal layer in a CMOS chip in which the image sensor 102 is formed. Thereby, the image sensor 102 and the first aperture layer 110 can be formed in the same manufacturing process. The first aperture layer 114 may thus be a metal layer. The first aperture layer 114 may also be a metal oxide (black chrome) or a black polymer (photoresist) layer which is non-transparent in the visible range. The first and second transparent layers 112, 116 may be spin-coated polymer layers. In applications where the first and second transparent layers 112, 116 are spin-coated, it simplifies the manufacturing process if also the second aperture layer 114 is spin coated, and it may then be formed by e.g. a black photoresist. It would also be possible to form either one or both of the first and second aperture layer(s) on a separate sheet of transparent material, such as glass, and to subsequently arrange the aperture layer(s) and glass sheet onto the image sensor 102.

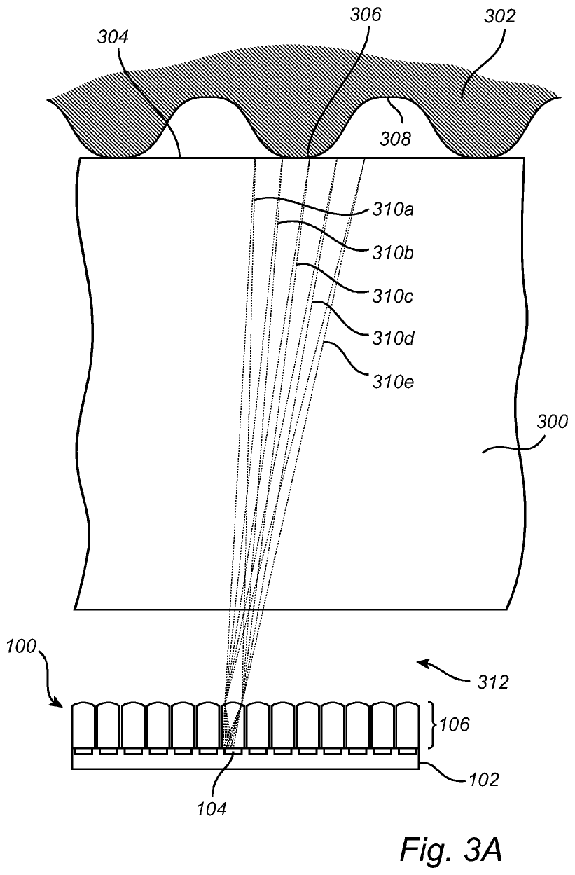

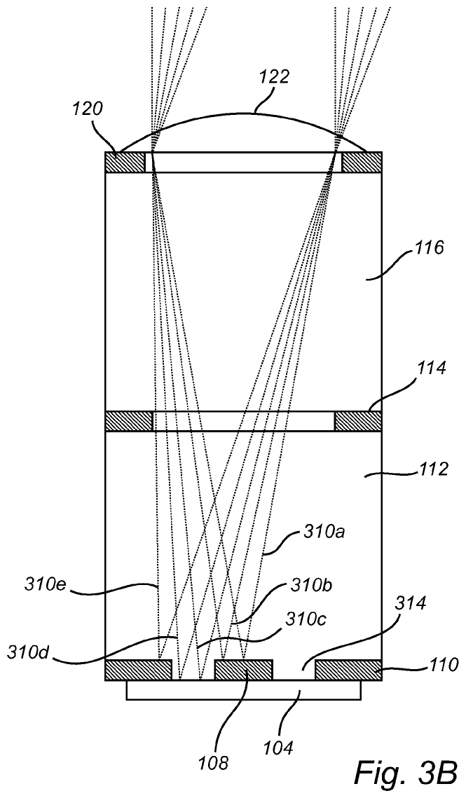

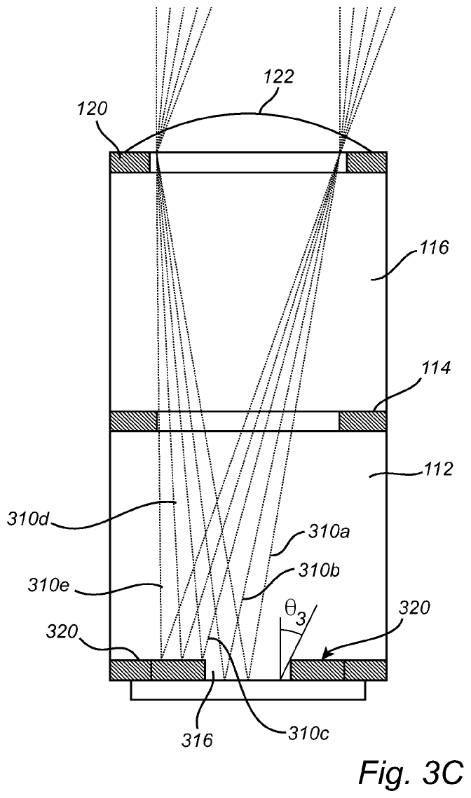

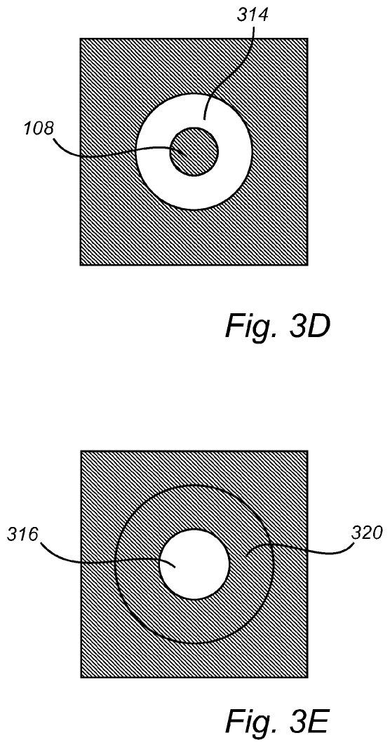

FIG. 3A is a schematic illustration of a biometric imaging device 100 arranged under a display panel 300 and FIG. 3B illustrates a collimating structure 106 according to an embodiment of the invention. A finger 302 is in contact with an outer surface 304 of the display panel 300, such as a cover glass, where fingerprint ridges 306 and valleys 308 can be seen. In the illustrated implementation, there is an air gap 312 between the bottom surface of the display panel 300 and the microlenses 118 of the biometric imaging device 100.

The light bundles 310a-e schematically illustrate light reaching the collimating structure with different incident angles, where the first light bundle 310a illustrates orthogonal light and where the fifth light bundle 310e illustrates light with the highest incident angle at the image sensor. In FIG. 3B, a collimating structure 106 comprising a light-blocking element 108 is illustrated. The light blocking element 108 is a circular structure arranged in the center of a circular aperture of the first aperture layer 110 such that an annulus-shaped opening 314 is formed, as is further illustrated in the top view of FIG. 3D. The first to fourth light bundles 310a-d illustrate light having an incident angle which is lower than the first predetermined incident angle Θ₁ thereby being allowed to pass through the collimating structure 106, while the fifth light bundle 310e represents light having an incident angle higher than Θ₁ which is thereby blocked by the collimating structure 106. Furthermore, the first and second light bundles 310a-b illustrate light having an incident angle which is lower than the second predetermined incident angle Θ₂, resulting in that such light is blocked by the light-blocking element 108 and prevented from reaching the photodetector pixel 104. Accordingly, in the illustrated collimating structure 106, only light having an incident angle between the first and second predetermined incident angles Θ₁ and Θ₂ reach a pixel 104 the image sensor 102.

The collimating structures 106 and the light-blocking elements 108 are preferably configured such that biometric images formed based on pixels receiving light from collimating structures having a light-blocking element 108 has a first contrast type and biometric images formed based on pixels receiving light from collimating structures 106 without a light-blocking element have a second contrast type different from the first contrast type.

The acceptance angle of the collimating structure 106 can be further controlled by introducing a horizontal offset between the microlens 118 and the corresponding aperture in the first aperture layer 110.

FIG. 3C illustrates a collimating structure 106 comprising an angle-limiting element 320, and a top view of the angle-limiting element 320 is illustrated in FIG. 3E. The angle-limiting element 320 is configured to limit the angle of incident light reaching the image sensor so that it is lower than a third predetermined incident angle Θ₃, with the third predetermined incident angle Θ₃ being lower than the first incident angle Θ₁, Θ₃<Θ₁. Moreover, Θ₃ may be equal to Θ₂. In practice, the angle-limiting element 320 could be implemented by a collimating structure having a lower acceptance angle, at least for a selected wavelength. Thereby, the angle-limiting element 320 could be part of the collimating structure 106.

In FIG. 3C, light having the lowest incident angles, i.e. 310a-b, reach the image sensor while light with higher incident angles, i.e. 310c-d, is blocked by the angle-limiting element. The angle limiting element 320 may have the same size as the previously described annular opening 314 such that the opening 316 of the collimating structure with the angle-limiting element 320 has the same size as the light-blocking element 108. Thereby, only light with incident angles being blocked by the light-blocking element 108 reaches the image sensor 102 for collimating structures with an angle-limiting element 320, i.e. Θ₃=Θ₂.

By means of the collimating structures 106 comprising light-blocking elements 108 and angle-limiting elements 320, it is possible to form complimentary images with different contrast types as will be described in further detail in the following.

The specific configuration of the collimating structures, light-blocking elements and angle-limiting elements depends in part on properties of the display panel and of the image sensor. The collimating structures are advantageously configured to suit a specific implementation such that images with the two different contrasts can be captured.

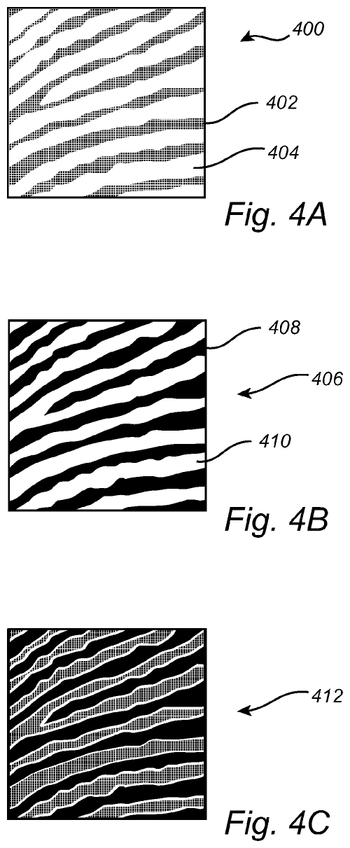

FIGS. 4A-C schematically illustrate the two contrast types and a combination of the two contrast types. FIG. 4A schematically illustrates an image 400 of a finger captured using collimating structures having a light-blocking element such that orthogonal and near-orthogonal light is prevented from reaching the image sensor. The first contrast type, based on light reaching the pixel from the wider angles, will then be “camera-like” where the valleys 402 are relatively darker and the ridges 404 are relatively brighter in the image 400.

FIG. 4B schematically illustrates an image 406 of a finger captured using collimating structures having an angle-limiting element such that only orthogonal and near-orthogonal light reaches the image sensor. The second contrast type, based on light reaching the pixel from the narrower angles, will then be of “index-matched-type” where the ridges 408 are relatively darker and the valleys 410 are relatively lighter in the image 406. In some implementations, the second contrast type may arise due to boundary mismatch causing differences in reflectivity.

In FIG. 4C, an image consisting of a combination of the two contrast types is schematically illustrated.

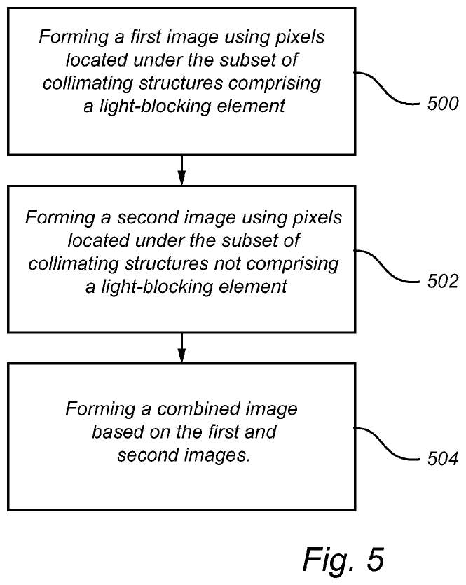

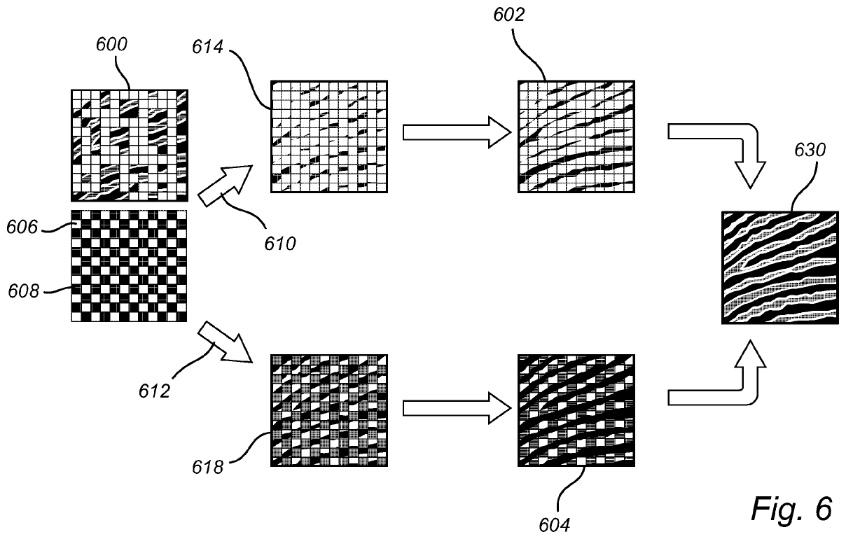

FIG. 5 is a flow chart outlining the general steps of a method according to the invention. The method will be described with further reference to FIG. 6 schematically illustrating steps of the method. The method comprises forming 500 a first image 602 using pixels located under the subset 606 of collimating structures comprising a light-blocking element; forming 502 a second image 604 using pixels located under the subset 608 of collimating structures not comprising a light-blocking element; and forming 504 a combined image 630 based on the first and second images 602, 604.

In FIG. 6, a biometric imaging device 100 is illustrated which comprises an array of collimating structures where a subset 606 of the collimating structures comprises a light-blocking element 108 as described earlier. The remaining collimating structures 608 does not comprise a light-blocking element, such that a checkerboard pattern is formed. A single image capture is performed to capture an image 600 after which the image processing is split into two separate image processing streams 610, 612. Each of the two image processing streams 610, 612 will process an image having a resolution which is approximately half of the full resolution of the image sensor. The first image processing stream 610 deals with the pixels located under collimating structures with the light-blocking element. In the illustrated example, the pixels 614 of the captured image 600 corresponding to one subset 606 of collimating structures is up-sampled to form an interpolated image, and after analysis of the interpolated image, a fingerprint image 602 showing only the first contrast type based on light with an incident angle between Θ₁ and Θ₂ is formed.

In the second image processing stream 612, the pixels located under collimating structures without a light-blocking element are handled. Here, the pixels 618 of the captured image 600 corresponding to the complementary subset 608 is up-sampled to form an interpolated image, and after analysis of the interpolated image, a fingerprint image 604 showing both contrast types based on light is having an incident angle lower than Θ₁ is formed. Based on the two fingerprint images 602, 604 from the corresponding two image processing streams, 610, 612, a combined fingerprint image 630 can be formed.

The described method can be implemented in a similar manner in an imaging device comprising collimating structures with light blocking elements, and the combination of collimating structures with or without light blocking and/or angle limiting elements can be configured so that the properties of the imaging device is suitable for a given application.

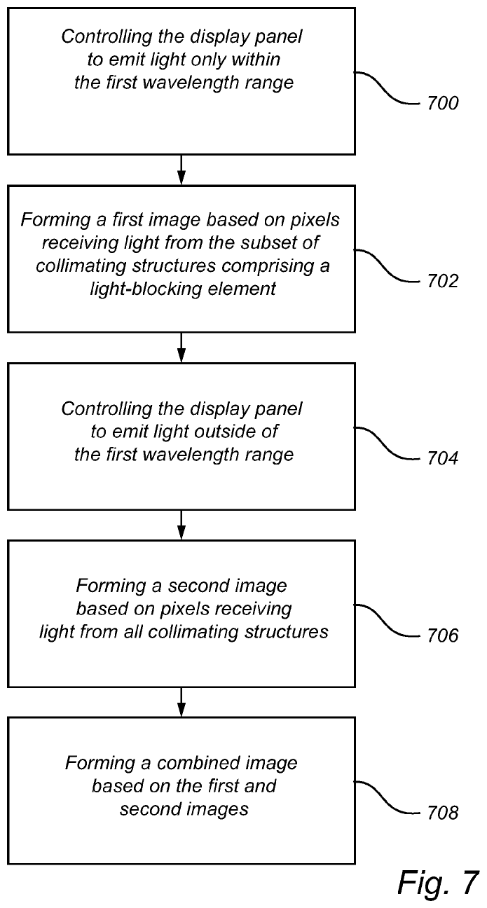

FIG. 7 is a flow chart outlining the general steps of an embodiment of the invention for an image sensor similar to the image sensor described with reference to FIG. 6, but with the difference that the light-blocking element is configured to block light within a first predetermined wavelength range. The light blocking element may thus act as a band-stop filter, or as a band-pass filter in which case the first wavelength range will be defined by two separate ranges. A subset of the light-blocking elements may also be opaque so that all visible light is blocked.

The method comprises controlling 700 the display panel to emit light only within the first wavelength range, forming 702 a first image based on pixels receiving light from the subset of collimating structures comprising a light-blocking element; controlling 704 the display panel to emit light outside of the first wavelength range; forming 706 a second image based on pixels receiving light from all collimating structures; and forming 708 a combined image based on the first and second images.

The first image will then exhibit a single contrast type based on non-orthogonal light, and it will have approximately half of the full resolution of the image sensor. The second image will show both contrasts and have the full resolution of the image sensor. Accordingly, by using a light-blocking element also acting as an optical filter, it is possible to form one image with full resolution.

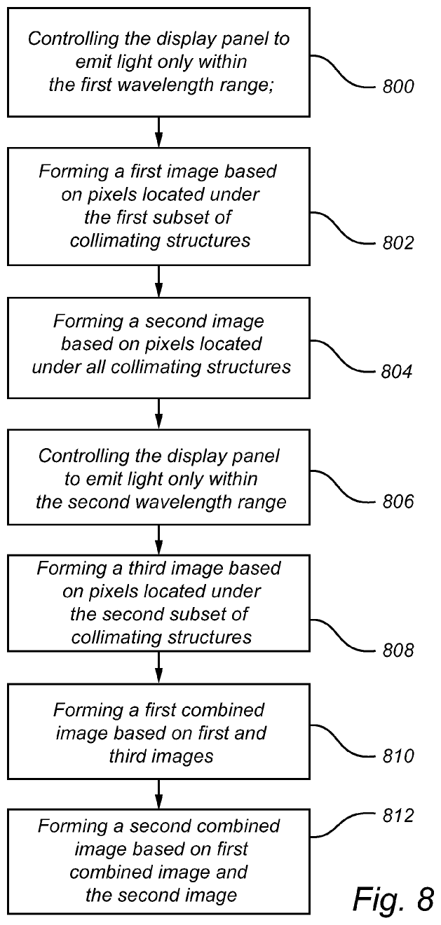

FIG. 8 is a flow chart outlining the general steps of an embodiment of the invention for an image sensor where all of the collimating structures comprise light-blocking elements, and wherein the light-blocking element of the first subset of collimating structures is configured to block light within a first predetermined wavelength range, and wherein the light-blocking elements of the second subset of collimating structures are configured to block light within a second predetermined wavelength range different from the first wavelength range. The first and second subsets may for example form a checkerboard pattern.

The method comprises controlling 800 the display panel to emit light only within the first wavelength range; forming 802 a first image based on pixels located under the first subset of collimating structures; forming 804 a second image based on pixels located under all collimating structures; controlling 806 the display panel to emit light only within the second wavelength range; forming 808 a third image based on pixels located under the second subset of collimating structures; forming 810 a first combined image based on first and third images; and forming 812 a second combined image based on first combined image and the second image.

The first image will have a single contrast type based on non-orthogonal light for the first subset of collimating structures, the second image will have dual contrast and full resolution and the third image will have single contrast based on non-orthogonal light for the second subset of collimating structures. Thereby, by combining the first and third images, a full resolution image for the non-orthogonal light can be achieved, and biometric analysis can be performed based on two full resolution images, one with only one contrast type and one with dual contrast.

The above described embodiments can be used and/or complemented with collimating structures comprising angle-limiting elements, which also may act as wavelength filters, thereby making the possible combinations endless. For a specific implementation, it will thus be possible to find a suitable balance between device complexity and biometric accuracy.

Even though the invention has been described with reference to specific exemplifying embodiments thereof, many different alterations, modifications and the like will become apparent for those skilled in the art. Also, it should be noted that parts of the device may be omitted, interchanged or arranged in various ways, the device yet being able to perform the functionality of the present invention.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage.

1. An optical biometric imaging device comprising:
an image sensor comprising a plurality of photodetector pixels;
a plurality of collimating structures arranged above the image sensor, the collimating structures being configured to limit the incident angle of light reaching the image sensor to be lower than a first predetermined incident angle Θ₁;
wherein at least a subset of the collimating structures comprises a light-blocking element configured to block light having an incident angle lower than a second predetermined incident angle Θ₂, the second incident angle being lower than the first incident angle, wherein the light-blocking element is configured to allow light having an incident angle between the first and second predetermined incident angles to pass, and wherein the light-blocking element is configured to block light within a first predetermined wavelength range.

2. The biometric imaging device according to claim 1, wherein the light-blocking elements are configured such that biometric images formed based on pixels receiving light from collimating structures having a light-blocking element has a first contrast type and biometric images formed based on pixels receiving light from collimating structures without a light-blocking element have a second contrast type different from the first contrast type.

3. The biometric imaging device according to claim 1, wherein every second collimating structure in the array of collimating structures comprises a light-blocking element.

4. The biometric imaging device according to claim 1, wherein a first subset of collimating structures comprises light-blocking elements configured to block light within a first predetermined wavelength range, and a second subset of collimating structures comprises light-blocking elements configured to block light within a second predetermined wavelength range different from the first wavelength range.

5. The biometric imaging device according to claim 1, wherein the collimating structure comprises:
a first aperture layer arranged above the image sensor;
a first transparent layer arranged above the first aperture layer; and
an array of microlenses arranged above the first transparent layer.

6. The biometric imaging device according to claim 5, further comprising:
a second aperture layer arranged on the first transparent layer; and
a second transparent layer arranged on the second aperture layer, wherein the array of microlenses is arranged on the second transparent layer.

7. The biometric imaging device according to claim 6, wherein the light-blocking element is located in an aperture of the first or second aperture layer.

8. The biometric imaging device according to claim 6, wherein the light-blocking element is arranged in a central portion of the aperture of the first or second aperture layer.

9. The biometric imaging device according to claim 6, wherein the light-blocking element is arranged between the first aperture layer and the second aperture layer.

10. The biometric imaging device according to claim 1, wherein at least a subset of the collimating structures comprises an angle-limiting element configured to limit the angle of incident light reaching the image sensor to be lower than a third predetermined incident angle Θ₃, the third predetermined incident angle being lower than the first incident angle.

11. The biometric imaging device according to claim 10, wherein the subset of collimating structures comprising an angle-limiting element is non-overlapping with the subset of collimating structures comprising a light-blocking element.

12. The biometric imaging device according to claim 10, wherein the angle-limiting element is configured to block light within a first predetermined wavelength range.

13. A display arrangement comprising:
a display panel having an array of light emitting elements; and
a biometric imaging device according to claim 1 arranged underneath the display panel.

14. A display arrangement comprising:
a display panel having an array of light emitting elements; and
a biometric imaging device according to claim 1 arranged underneath the display panel, wherein the biometric imaging device is configured to capture an image when the display panel is controlled to emit light only within the first wavelength range.

15. Method of imaging in a biometric imaging device comprising:
an image sensor comprising a plurality of photodetector pixels and a plurality of collimating structures arranged above the image sensor, the collimating structures being configured to limit the incident angle of light reaching the image sensor to a first predetermined incident angle, wherein at least a subset of the collimating structures comprises a light-blocking element configured to block light having an incident angle lower than a second predetermined incident angle, the second incident angle being lower than the first incident angle, and wherein the light-blocking element is configured to allow light having an incident angle between the first and second incident angles to pass, the method comprising:
forming a first image using pixels located under the subset of collimating structures comprising a light-blocking element;
forming a second image using pixels located under the subset of collimating structures not comprising a light-blocking element; and
forming a combined image based on the first and second images.

16. Method of imaging in a biometric imaging device arranged under a display panel comprising a plurality of light emitting elements, the biometric imaging device comprising:
an image sensor having a plurality of photodetector pixels and a plurality of collimating structures arranged above the image sensor, the collimating structure being configured to limit the incident angle of light reaching the image sensor to a first predetermined incident angle, wherein at least a subset of the collimating structures comprises a light-blocking element configured to block light having an incident angle lower than a second predetermined incident angle, the second incident angle being lower than the first incident angle, the light-blocking element being configured to allow light having an incident angle between the first and second incident angles to pass, and wherein the light-blocking element is configured to block light within a first predetermined wavelength range, the method comprising:
controlling the display panel to emit light only within the first wavelength range;
forming a first image based on pixels receiving light from the subset of collimating structures comprising a light-blocking element;
controlling the display panel to emit light outside of the first wavelength range;
forming a second image based on pixels receiving light from all collimating structures; and
forming a combined image based on the first and second images.

17. Method of imaging in a biometric imaging device arranged under a display panel comprising a plurality of light emitting elements, the biometric imaging device comprising:
an image sensor comprising a plurality of pixels forming a photodetector pixel array and an array of collimating structures arranged above the image sensor, the collimating structure being configured to limit the incident angle of light reaching the image sensor, wherein a first subset of the collimating structures comprises a light-blocking element configured to block light having an having an incident angle lower than a second predetermined incident angle, the second incident angle being lower than the first incident angle, the light-blocking element of the first subset of collimating structures being configured to allow light having an incident angle between the first and second incident angles to pass, and wherein the light-blocking element of the first subset of collimating structures is configured to block light within a first predetermined wavelength range,
and a second subset of the collimating structures comprises a light-blocking element configured to block light having an having an incident angle lower than the second predetermined incident angle, the light-blocking element of the second subset of collimating structures being configured to allow light having an incident angle between the first and second incident angles to pass, and wherein the light-blocking elements of the second subset of collimating structures are configured to block light within a second predetermined wavelength range different from the first wavelength range, the method comprising:
controlling the display panel to emit light only within the first wavelength range;
forming a first image based on pixels located under the first subset of collimating structures;
forming a second image based on pixels located under all collimating structures;
controlling the display panel to emit light only within the second wavelength range;
forming a third image based on pixels located under the second subset of collimating structures;
forming a first combined image based on first and third images; and
forming a second combined image based on first combined image and the second image.
